(19) United States
(12) Patent Application Publication
(10) Pub. No.: US 2003/0017678 A1
(43) Pub. Date: Jan. 23, 2003

(54) Method of reducing stress and encroachment effect of isolation device on active regions

(75) Inventor: Shu-Ya Hsu, Yun-Lin (TW)

Correspondence Address: LOWE HAUPTMAN GILMAN & BERNER, LLP, 1700 Diagonal Road, Suite 310, Alexandria, VA, 22314, US

(73) Assignee: Macronix International Co., Ltd.

(21) Appl. No.: 09/908,703

(22) Filed: Jul. 20, 2001

(51) Int. Cl. H01L 21/76

(52) U.S. Cl. 438/437; 438/429; 438/435

(57) ABSTRACT

The present invention provides a method of retarding oxidation rate of a side-wall of an isolation device. The method comprises providing a semiconductor substrate having at least a trench structure thereon. The trench structure is filled with an insulating material to form the isolation device and then the isolation device is subjected to dry oxidation whereby retards the oxidation rate of the side-wall of the isolation device. The stress and encroachment effects on the active regions nearby the isolation device can be reduced because of the retarded oxidation rate.

### BACKGROUND OF THE INVENTION

1. Field of the Invention

The invention relates to a method of forming isolation devices, and more particularly to a method of forming shallow trench isolation devices whereby reduces stress effect and encroachment of active regions.

2. Description of the Prior Art

It is a conventional method to isolate devices in an integrated circuit by using shallow-trench isolation. Generally, an anisotropic etching process is performed with using silicon nitride as a mask to form steep trenches on a semiconductor substrate. Then, by filling the trenches with oxide, shallow-trench isolations, which have top surfaces are in level with the top surface of the substrate, are formed on the substrate.

FIGS. 1A through 1D are cross-sectional views showing a conventional method forming a shallow-trench isolation.

Referring to FIG. 1A, a pad oxide layer 122 is formed on a silicon substrate 110 for protecting the substrate 110, wherein the pad oxide layer 122 is removed before the formation of a gate oxide layer. A silicon nitride layer 124 is formed on the pad oxide layer 122 by performing a chemical vapor deposition (CVD). Then, an etching process is performed on the silicon substrate 110 by using a patterned photoresist layer 128 as a mask to form multitudes of trench structures 130 on the silicon substrate 110, wherein the photoresist layer 128 is removed after the etching process.

Referring to FIG. 1B, a side-wall oxide layer 131 is formed at side walls of the trench structures 130 by performing a thermal oxidation process, and then, a silicon oxide layer 132 is filled in the trench structures 130 and on the surface of the silicon substrate 110.

Referring to FIG. 1C, the silicon oxide layer 132 on the silicon nitride layer 124 is removed by performing a chemical mechanical polishing (CMP) process after a densification process, such as wet side-wall re-oxidation, is performed on the oxide layer 132 to form multitudes of shallow trench isolation devices 134.

Referring to FIG. 1D, the silicon nitride layer 124 is stripped by using hot phosphoric acid.

However, there is a consideration to stress for applying the conventional process mentioned above on the higher integrated circuit fabrication, such as 0.25-micrometer process. For example, the application of the wet side-wall re-oxidation may cause stress damage and encroachment on the active regions of the devices, which may further result in current reduction and reliability degradation.

### SUMMARY OF THE INVENTION

It is an object of the present invention to provide a method of forming a shallow trench isolation. Dry side-wall re-oxidation replaces a conventionally wet one during densification of the shallow trench isolation.

It is another object of the present invention to provide a method for reducing the stress effect of isolation device on active region. The dry side-wall re-oxidation applied in the densification process of shallow trench isolation can reduce the stress at the side-wall of the isolation device.

It is yet an object of the present invention to provide a method for reducing encroachment effect of the isolation device for the active region. The dry side-wall re-oxidation applied in the densification process of shallow trench isolation can retard re-oxidation at the side-wall of the isolation device.

In the present invention, a method of retarding oxidation rate of a side-wall of an isolation device comprises providing a semiconductor substrate having at least a trench structure thereon. The trench structure is filled with an insulating material to form the isolation device and then the isolation device is subjected to dry oxidation whereby retards the oxidation rate of the side-wall of the isolation device. The stress and encroachment effects on the active regions nearby the isolation device can be reduced because of the retarded oxidation rate.

### BRIEF DESCRIPTION OF THE DRAWINGS

A better understanding of the invention may be derived by reading the following detailed description with reference to the accompanying drawing wherein:

FIGS. 1A-1D are a series of cross-sectional schematic diagrams illustrating the formation of the shallow trench isolation in accordance with the prior art; and

FIGS. 2A-2E are a series of cross-sectional schematic diagrams illustrating the formation of the shallow trench isolation in accordance with the present invention.

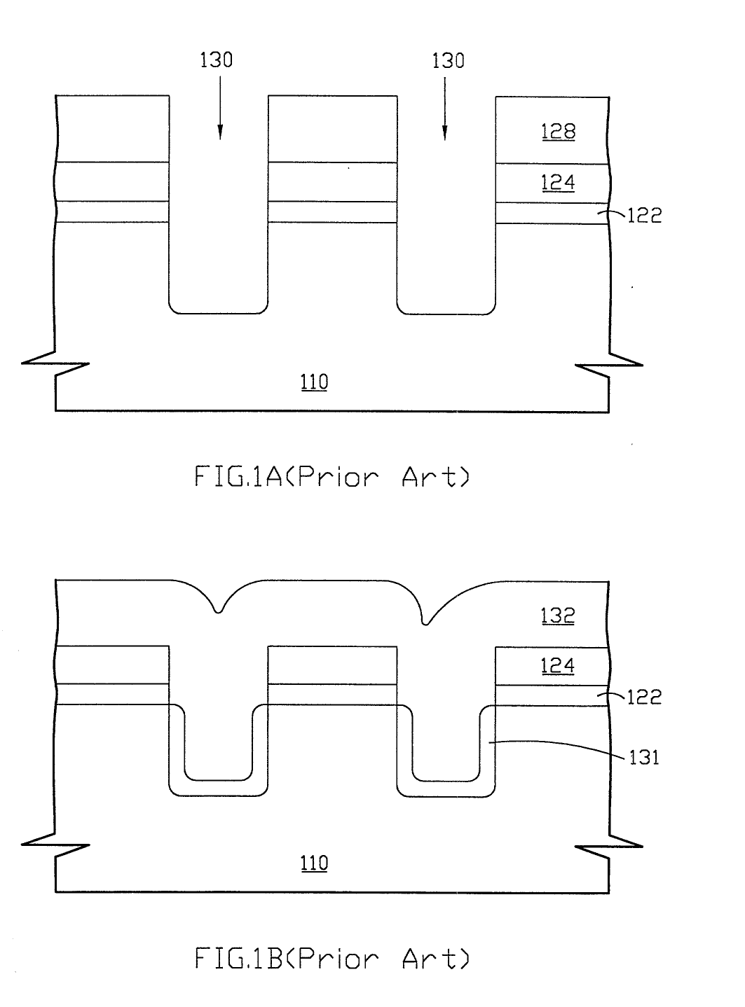

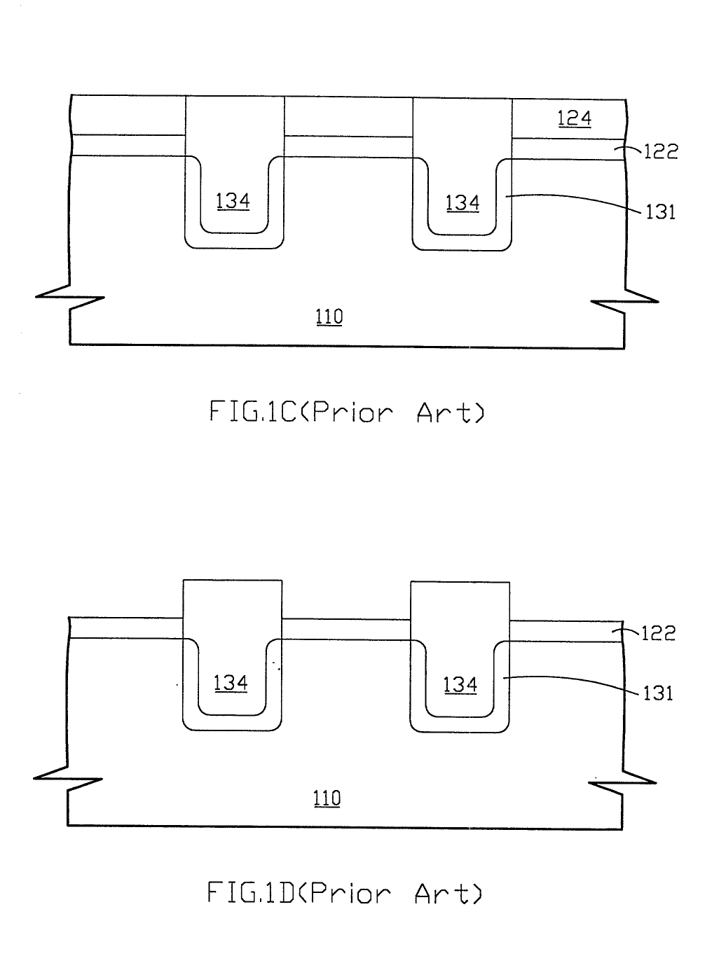

### DESCRIPTION OF THE PREFERRED EMBODIMENT

The semiconductor devices of the present invention are applicable to a board range of semiconductor devices and can be fabricated from a variety of semiconductor materials. While the invention is described in terms of a single preferred embodiment, those skilled in the art will recognize that many steps described below can be altered without departing from the spirit and scope of the invention.

Furthermore, there is shown a representative portion of a semiconductor structure of the present invention in enlarged, cross-sections of the two dimensional views at several stages of fabrication. The drawings are not necessarily to scale, as the thickness of the various layers are shown for clarify of illustration and should not be interpreted in a limiting sense. Accordingly, these regions will have dimensions, including length, width and depth, when fabricated in an actual device.

In the present invention, a method of reducing stress effect of an isolation device on a plurality of active regions comprises first providing a semiconductor substrate. At least a trench structure is formed on the semiconductor substrate and between the active regions. The trench structure is subjected to first oxidation and then an insulating layer is deposited into the trench structure to form the isolation device. The isolation device is subjected to second oxidation in an environment containing nitrogen gas whereby reduces the stress and encroachment effects of the isolation device on the active regions.

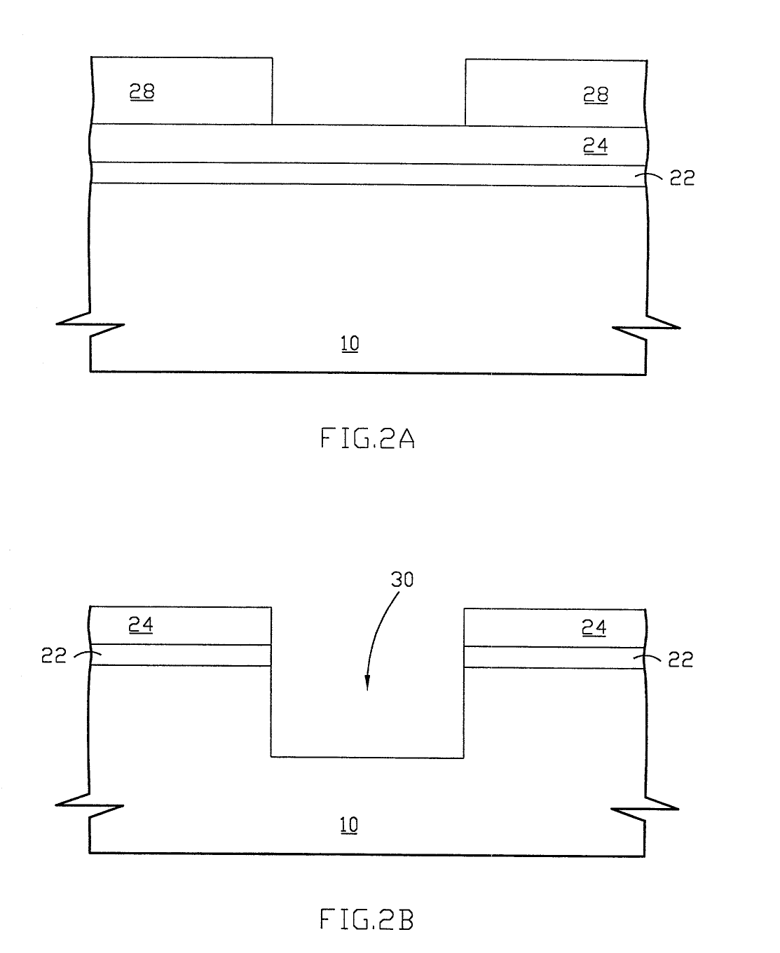

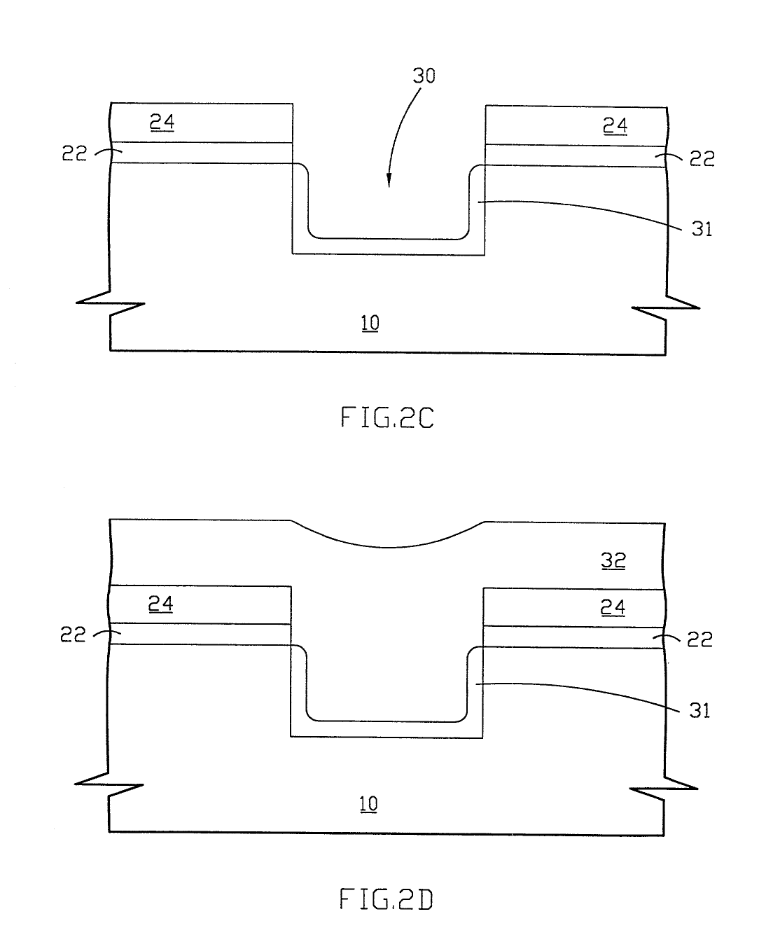

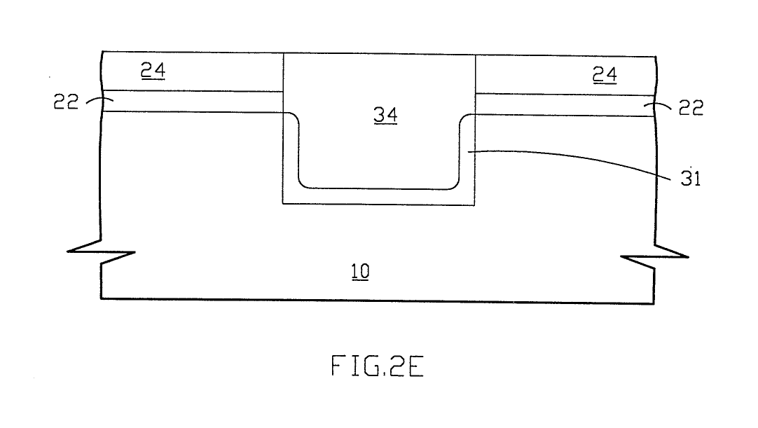

One embodiment of the present invention is depicted in FIGS. 2A-2E. First referring to FIG. 2A, a semiconductor substrate 10, such as a silicon substrate, is provided and a pad oxide layer 22 is formed thereon for protecting the semiconductor substrate 10. A silicon nitride layer 24 is formed on the pad oxide layer 22 by using the method of chemical vapor deposition (CVD). A patterned photoresist layer 28 as a mask is formed on the silicon nitride layer 24.

Next referring to FIG. 2B, an etching process is performed on the silicon nitride layer 24, the pad oxide layer 22, and the semiconductor substrate 10 in order to form a trench structure 30 on the semiconductor substrate 10. Then the photoresist layer 28 is removed after the etching process.

Referring to FIG. 2C, a side-wall oxide layer 31 is formed at side wall of the trench structure 30 by performing a thermal oxidation process. Next shown in FIG. 2D, a silicon oxide layer 32 is filled in the trench structure 30 and on the surface of the silicon nitride layer 24. Then shown in FIG. 2E, as a key step of the present invention, the densification of the silicon oxide layer 32 is performed by dry side-wall re-oxidation instead of conventionally wet one. Instead of hydrogen gas, nitrogen gas is used in the dry side-wall re-oxidation and thus reduces the re-oxidation rate of the side-wall of the trench structure. The retardation of re-oxidation rate can reduce the growing thickness of undesired oxide that may result in the encroachment and the stress effects on active regions. Next, the planarization of the silicon oxide layer 32 is performed by chemical mechanical polishing (CMP) process after the densification process and a shallow trench isolation device 34 is performed.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method of retarding oxidation rate of a side-wall of an isolation device, said method comprising:
providing a semiconductor substrate having at least a trench structure thereon;
filling said trench structure with an insulating material to form said isolation device; and
subjecting said isolation device to dry oxidation whereby retards the oxidation rate of said side-wall of said isolation device.

2. The method according to claim 1, wherein said insulating material comprises silicon oxide.

3. The method according to claim 1, wherein said dry oxidation is implemented in an environment containing nitrogen gas.

4. A method of reducing stress effect of an isolation device on a plurality of active regions, said method comprising:
providing a semiconductor substrate;
forming at least a trench structure on said semiconductor substrate, said trench structure between said active regions;
subjecting said trench structure to first oxidation;
depositing an insulating layer into said trench structure to form said isolation device; and
subjecting said isolation device to second oxidation in an environment containing nitrogen gas whereby reduces the stress effect of said isolation device on said active regions.

5. The method according to claim 4, wherein said insulating layer comprising a silicon oxide layer.

6. A method of reducing encroachment effect of an isolation device on a plurality of active regions, said method comprising:
providing a silicon substrate;
forming at least a trench structure between said active regions and on said silicon substrate, said trench structure having a side-wall;
subjecting said side-wall to oxidation;
depositing an insulating layer into said trench structure to form said isolation device; and
subjecting said side-wall to re-oxidation, said re-oxidation implemented in an environment containing nitrogen gas.

7. The method according to claim 6, wherein said forming step comprises:
forming a pad oxide layer on said silicon substrate;
forming a dielectric layer on said pad oxide layer;
forming a photo-resist layer on said dielectric layer, said photo-resist layer exposing a portion of said dielectric layer where said trench structure is formed;
removing said portion of said dielectric layer and said pad oxide layer to expose said portion of said silicon substrate; and
etching exposed said silicon substrate to form said trench structure.

8. The method according to claim 7, wherein said dielectric layer comprises a silicon nitride layer.

9. The method according to claim 6, wherein said insulating layer comprises a silicon oxide layer.
